(19) United States
(12) Patent Application Publication
(10) Pub. No.: US 2026/0293318 A1
(43) Pub. Date: Sep. 24, 2026

(54) Semiconductor Device Including Cells with Varying Cell Heights and Method of Manufacturing the Same

(71) Applicant: Taiwan Semiconductor Manufacturing Company, Ltd., Hsinchu (TW)

(72) Inventors: Jun-Yu Lin, Hsinchu (TW); Shih-Wei Peng, Hsinchu (TW); Sheng-Feng Huang, Hsinchu (TW); Wei-Cheng Kang, Hsinchu (TW); Wei-Cheng Tzeng, Hsinchu (TW); Jiann-Tyng Tzeng, Hsinchu (TW)

(21) Appl. No.: 19/083,534

(22) Filed: Mar. 19, 2025

(51) Int. Cl. H10D 89/10; H01L 23/528

(52) U.S. Cl. CPC H10D 89/10; H10W 20/427

(57) ABSTRACT

A device includes a plurality of cells, a plurality of active regions, a plurality of gate regions, a plurality of sources and drains, and plurality of power rails. The cells include one or more taller cells, one or more shorter cells, and one or more one-half-height (OHH) cells. The shorter cell has a smaller cell height than the taller cell. The OHH cell has a cell height larger than the cell height of the taller cell. The active regions are formed in each cell. The gate region extends across the active regions. The sources and drains are formed in the active regions on opposite sides of the gate region. The power rails include first and second power rails respectively defining top and bottom boundaries of a cell. A method for manufacturing the device is also disclosed.

### BACKGROUND

In semiconductor design, a cell serves as the basic building block of a device, such as an integrated circuit (IC). Each cell is a circuit designed to perform specific functions, ranging from simple logic gates like AND and OR to more complex components like flip-flops and multiplexers. They can be categorized as standard cells, which are pre-designed, characterized, and stored in a standard cell library. These libraries are accessible to electronic design automation (EDA) tools, which use them to generate, optimize, and verify IC designs. The IC designs are evaluated based on performance, power, and area (PPA), with design trade-offs made to balance speed, energy efficiency, and physical footprint.

### BRIEF DESCRIPTION OF THE DRAWINGS

Aspects of the present disclosure are best understood from the following detailed description when read with the accompanying figures:

FIG. 1 is a schematic diagram illustrating an exemplary layout in accordance with various embodiments of the present disclosure;

FIG. 2 is a schematic diagram illustrating another exemplary layout in accordance with various embodiments of the present disclosure;

FIG. 3 is a schematic diagram illustrating another exemplary layout in accordance with various embodiments of the present disclosure;

FIG. 4 is a schematic diagram illustrating another exemplary layout in accordance with various embodiments of the present disclosure;

FIG. 5 is a schematic diagram illustrating another exemplary layout in accordance with various embodiments of the present disclosure;

FIG. 6 is a schematic diagram illustrating another exemplary layout in accordance with various embodiments of the present disclosure;

FIG. 7 is a schematic diagram illustrating another exemplary layout in accordance with various embodiments of the present disclosure;

FIG. 8 is a schematic diagram illustrating another exemplary layout in accordance with various embodiments of the present disclosure;

FIG. 9 is a schematic diagram illustrating another exemplary layout in accordance with various embodiments of the present disclosure;

FIG. 10 is a schematic diagram illustrating another exemplary layout in accordance with various embodiments of the present disclosure;

FIG. 11 is a schematic diagram illustrating another exemplary layout in accordance with various embodiments of the present disclosure;

FIG. 12 is a schematic diagram illustrating another exemplary layout in accordance with various embodiments of the present disclosure;

FIG. 13 is a schematic diagram illustrating another exemplary layout in accordance with various embodiments of the present disclosure;

FIG. 14 is a schematic diagram illustrating another exemplary layout in accordance with various embodiments of the present disclosure;

FIG. 15 is a flowchart of an exemplary method of manufacturing a device in accordance with various embodiments of the present disclosure;

FIG. 16 is schematic block diagram of an exemplary electronic design automation (EDA) system in accordance with various embodiments of the present disclosure; and

FIG. 17 is a schematic block diagram of an example integrated circuit (IC) manufacturing system in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underneath,” “below,” “lower,” “above,” “on,” “top,” “bottom” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

In semiconductor design, cells of substantially the same cell height are read from one or more cell libraries, and placed in an IC layout, e.g., by an electronic design automation (EDA) tool or system. While uniform cell height devices simplify design and manufacturing, they are less flexible for optimizing performance, power, and area (PPA). In certain examples described herein, systems and methods comprise a device that includes cells with varying heights. For example, the device includes first and second unit cells, each having a distinct cell height and a one-half-height cell (OHH) cell that has a cell height substantially equal to the sum of the cell height of the fist unit cell and half the cell height of the second unit cell. The construction as such enables design flexibility to optimize the balance among speed, energy efficiency, and physical footprint.

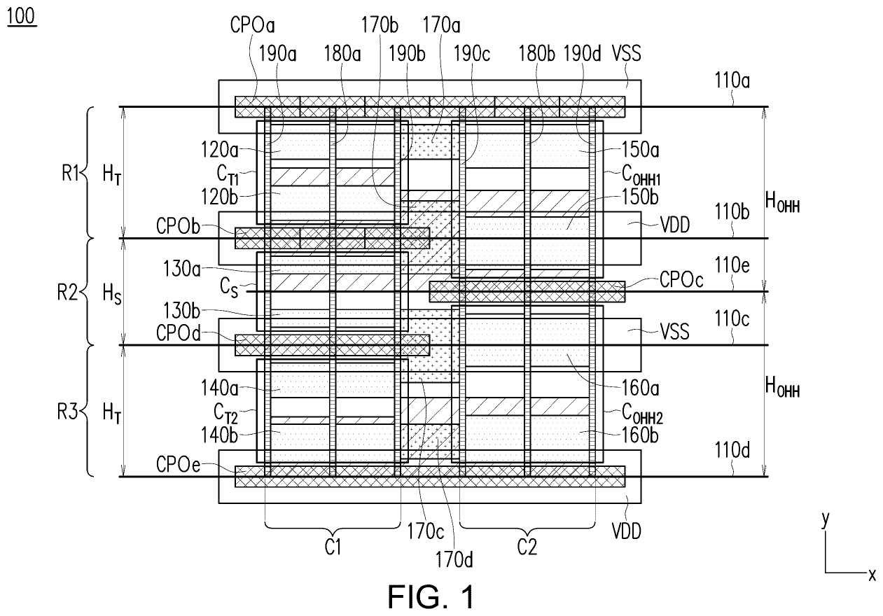

FIG. 1 is a schematic diagram illustrating an exemplary layout in accordance with various embodiments of the present disclosure. In FIG. 1, the example layout 100, or a device associated therewith, includes a plurality of cells (C_{T1}, C_{T2}, C_{S}, C_{OHH1}, C_{OHH2}) arranged in an array of rows (R1-R3) and columns (C1, C2). In certain embodiments, each cell (C_{T1}, C_{T2}, C_{S}, C_{OHH1}, C_{OHH2}) includes one or more logic gates (e.g., AND gate, OR gate, any suitable logic gate, or a combination thereof), flip-flops, multiplexers, and the like. The layout 100 may be generated by an EDA system, such as an automated placement and routing (APR), and stored in a non-transitory, computer-readable storage medium.

Each row (R1-R3) is defined by boundaries 110a-110d, each extending along a first direction (x), and a row height (H_{T}, H_{S}) corresponding to the distance along a second direction (y) transverse to the first direction (y) between the boundaries 110a-110d. The first column (C1) includes a plurality of unit cells, e.g., a pair of taller cells (C_{T1}, C_{T2}) and a shorter cell (C_{S}) disposed between the taller cells (C_{T1}, C_{T2}). The unit cells (C_{T1}, C_{T2}, C_{S}) may be arranged in sequence such that the taller cell (C_{T1}) is at the first row (R1), followed by the shorter cell in the second row (R2), and then another taller cell (C_{T2}) in the third row (R3). The taller cell (C_{T1}, C_{T2}) has a cell height that corresponds to the respective row height (H_{T}). The shorter cell (C_{S}) has a cell height that corresponds to the row height (H_{S}). In this exemplary embodiment, the cell height (H_{S}) is smaller than the cell height (H_{T}).

The taller cell (C_{T1}) includes first and second active regions 120a, 120b. The first active region 120a extends along the first direction (x) and has a first conductivity type (e.g., p-type). The second active region 120b is substantially parallel to the first active region 120a, is spaced apart from the first active region 120a along the second direction (y), and has a second conductivity type (e.g., n-type) different from the first conductivity type. The p-type active region 120a is formed over an n-type well region, while the n-type active region 120b is formed over a p-type well region.

The shorter cell (C_{S}) includes n- and p-type active regions 130a, 130b. The n-type active region 130a extends along the first direction (x) and is formed over a p-type well region. The p-type active region 130b is substantially parallel to the n-type active region 130a, is spaced apart from the n-type active region 130a along the second direction (y), and is formed over an n-type well region.

The taller cell (C_{T2}) includes p- and n-type active regions 140a, 140b. The p-type active region 140a extends along the first direction (x) and is formed over an n-type well region. The n-type active region 140b is substantially parallel to the p-type active region 140a, is spaced apart from the p-type active region 140a along the second direction (y), and is formed over a p-type well region.

The active regions 120a-140a, 120b-140b are functional active regions, each contributing to the operation of the device. In addition to the active regions, the layout 100 may further includes a plurality of non-functional (or dummy) active regions 170a-170d disposed between the first and second columns (C1, C2) across the first-third rows (R1-R3). Dummy active regions may either void of semiconductor components or include semiconductor components that are not electrically connected to the device. They are incorporated into the layout 100 to achieve uniformity in the fabrication process, such as maintaining consistent pattern density across the semiconductor die or minimizing process-induced variations like stress or loading effects during manufacturing. As such, while these regions do not actively participate in the operation of the device, they serve an auxiliary role in ensuring the structural and manufacturing integrity of the layout 100.

The second column (C2) includes a pair of OHH cell (C_{OHH1}, C_{OHH2}), each having a cell height (H_{OHH}) substantially equal to the sum of the cell height of a first unit cell in a row and half the cell height of a second unit cell in an adjacent row. In some embodiments, the cell height (H_{OHH}) is substantially equal to the sum of the cell height (H_{T}) and half the cell height (H_{S}). In such some embodiments, the OHH cell (C_{OHH1}) has a top edge that aligns with the top edge of the taller cell (C_{T1}) and a bottom edge that aligns with the center of the shorter cell (C_{S}). Similarly, the OHH cell (C_{OHH2}) has a bottom edge that aligns with the bottom edge of the taller cell (C_{T2}) and a bottom edge that aligns with the center of the shorter cell (C_{S}).

In other embodiments, the cell height (H_{OHH}) is substantially equal to the sum of the cell height (H_{S}) and half the cell height (H_{T}). In such other embodiments, the OHH cell (C_{OHH1}) has a bottom edge that aligns with the bottom edge of the shorter cell (C_{S}) and a top edge that aligns with the center of the taller cell (C_{T1}) or the OHH cell (COH_{H1}) has a top edge that aligns with the top edge of the shorter cell (C_{T}) and a bottom edge that aligns with the center of the taller cell (C_{T2}).

In this exemplary embodiment, the OHH cells (C_{OHH1}, C_{OHH2}) are defined by boundaries 110a, 110d, 110e and the cell height (H_{OHH}) corresponds to the distance between the boundaries 110a, 110d, 110e.

Each OHH cell (C_{OHH1}, C_{OHH2}) includes functional p- and n-type active regions 150a, 150b, 160a, 160b. The p-type active region 150a, 160a extends in the first direction (y) and is formed over an n-type well region. The n-type active region 150b, 150b is substantially parallel to the p-type active region 150a, 160a, is spaced apart from the p-type active region 150a, 160a along the second direction (y), and is formed over a p-type well region.

The layout 100 further includes gate regions, e.g., gate regions 180a, 180b, and source and drain regions formed in the active region 120a-160a, 120b-160b on opposite sides of the gate regions 180a, 180b. The gate regions 180a, 180b are functional gate structures (e.g., polysilicon or metal gates) electrically connected to the device. They are responsible for controlling the flow of current between the source and drain regions based on an applied voltage. In this exemplary embodiment, the gate region 180a, 180b extends from the boundary 110a, 110d to the boundary 110e through the boundary 110b, 110c and across the active regions 120a-160a, 120b-160b.

In addition to the gate regions 180a, 180b, the layout 100 further includes non-functional gate regions 190a-190d, which may also referred to as dummy gate regions. Dummy gate regions are not electrically connected to (or electrically active in) the device. They are incorporated into the layout to ensure manufacturing uniformity and process optimization, serving purposes such as maintaining consistent lithographic or etching conditions across the wafer (pattern density), reducing mechanical stress variations that could impact the performance of nearby functional gates (stress management), providing a uniform surface during planarization to prevent uneven material removal (CMP or Chemical Mechanical Polishing), and preserving the electrical behavior of neighboring functional gates by mitigating physical asymmetries in the layout (isolation and symmetry). In this exemplary embodiment, each gate region 190a-190d extends from the boundary 110a to the boundary 110d through the boundaries 110b, 110c, 110e along the edges of the active regions 120a-160a, 120b-160b, 170a-170d.

The layout 100 further includes cut regions (CPOa-CPOe), each forming gate regions for different cells (C_{T1}, C_{T2}, C_{S}, C_{OHH1}, C_{OHH2}). For example, the cut region (CPOa) extends along the boundary 110a and separates the gate regions 180a, 180b, 190a-190d of cells (C_{T1}, C_{OHH1}) from those of one or more adjacent cells above.

Each cut regions (CPOb) extends along the boundary 110b and separates the gate regions 180a, 190a, 190b of the cells (C_{T1}, C_{S}) from each other. The cut region (CPOc) extends along the boundary 110c and separates the gate regions 180a, 190a, 190b of the cells (C_{S}, C_{T2}) from each other. The cut region (CPOd) extends along the boundary 110d and separates the gate regions 180a, 180b, 190a-190d of the cells (C_{T2}, C_{OHH2}) from those of one or more adjacent cells below. The cut region (CPOe) extends along the boundary 110e and separates the gate regions 180b, 190c, 190d of the cells (C_{OHH1}, C_{OHH2}) from each other. In this exemplary embodiment, the cut region (CPOa-CPOe) includes a recess formed in the device and a dielectric material deposited in the recess.

The layout 100 further includes a plurality of power rails (VDD, VSS), each carrying either a supply voltage or a reference voltage (e.g., ground or a negative voltage). The power rails (VDD, VSS) each extend in the first direction (x) and are alternately arranged along the second direction (y). For example, each power rail (VSS) extends along the respective boundary 110a, 110d and overlaps the respective cut region (CPOa, CPOd). Similarly, each power rail (VDD) extends along the respective boundary 110b, 110d and overlaps the respective cut region (CPOb, CPOe).

From the above description, because the layout, or the device associated therewith, incorporates cells with varying cell heights, it enables design flexibility to optimize the balance among speed, energy efficiency, and physical footprint, commonly referred to as Performance, Power, and Area (PPA). By tailoring cell heights to suit specific functional requirements, the layout 100 can allocate resources more efficiently. For example, larger cells may be used where higher performance or greater drive strength is required, while smaller cells can reduce power consumption and save area in less critical regions. This strategic variation in cell dimensions contributes to achieving an overall optimal PPA for the layout 100.

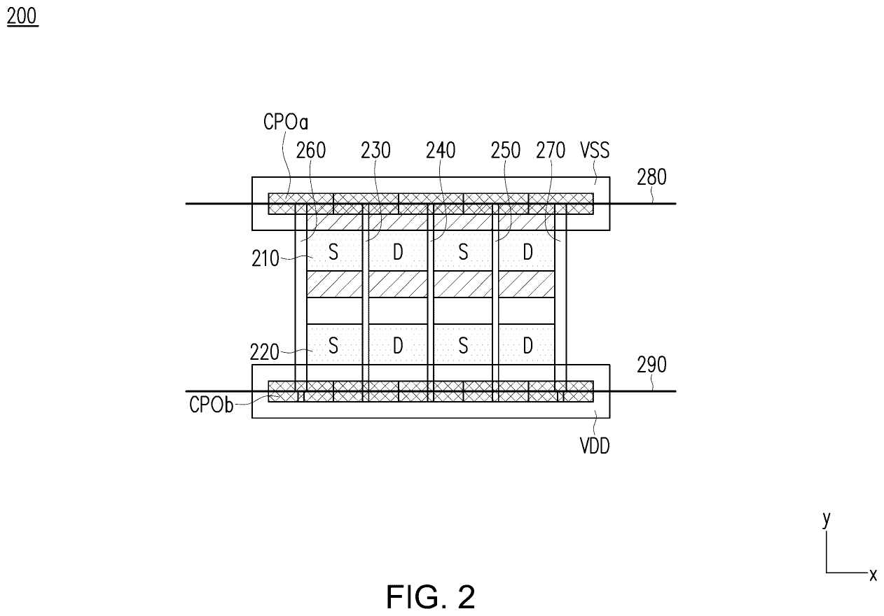

FIG. 2 is a schematic diagram illustrating another exemplary layout in accordance with various embodiments of the present disclosure. In FIG. 2, the example layout 200, or a unit cell (e.g., cell C_{T1}, C_{T2}, C_{S}) associated therewith, includes a pair of active regions 210, 220, a plurality of gate regions 230-270, source and drain regions (S, D), a pair of cut regions (CPOa, CPOb), and a pair of power rails (VDD, VSS). The layout 200 is defined by top and bottom boundaries 280, 290, each extending in the first direction (x), and a cell height that corresponds to the distance along the second direction (y) between the top and bottom boundaries 280, 290. The first active region 210 extends along the first direction (x) and has a first conductivity type (e.g., p-type). The second active region 220 is substantially parallel to the first active region 210, is spaced apart from the first active region 210 along the second direction (y), and has a second conductivity type (e.g., n-type) different from the first conductivity type. The p-type active region 210 is formed over an n-type well region, while the n-type active region 220 is formed over a p-type well region.

The gate regions 230-250 are functional gate structures (e.g., polysilicon or metal gates) electrically connected to the device. They are responsible for controlling the flow of current between the source and drain regions (S, D) based on an applied voltage. In this exemplary embodiment, each gate region 230-250 extends from the top boundary 280 to the bottom boundary 290 across the active regions 210, 220. The source and drain regions (S, D) are formed in the active regions 210, 220 on opposite sides of the gate region 230-250.

In addition to the gate regions 230-250, the layout 200 further includes non-functional gate regions 260, 270, which may also referred to as dummy gate regions. Dummy gate regions are not electrically connected to (or electrically active in) the device. In this exemplary embodiment, each gate region 260, 270 extends from the top boundary 280 to the bottom boundary 290 along the respective edge of the active region 210, 220.

Each cut region (CPOa, CPOb) forms gate regions for different cells. For example, the cut region (CPOa) extends along the top boundary 280 and separates the gate regions 230-270 of the unit cell 200 from those of one or more adjacent cells above. Similarly, the cut region (CPOb) extends along the bottom boundary 290 and separates the gate regions 230-270 of the unit cell 200 from those of one or more adjacent cells below. In this exemplary embodiment, the cut region (CPOa, CPOb) includes a recess formed in the cell 200 and a dielectric material deposited in the recess.

The power rails (VDD, VSS) each extend in the first direction (x) and are spaced apart from each other in the second direction (y). The power rail (VDD) carries a supply voltage, while the power rail (VSS) carries a reference voltage (e.g., ground or a negative voltage). Each power rail (VSS, VDD) extends along the respective boundary 280, 290 and overlaps the respective cut regions (CPOa, CPOb).

From the description above, because the layout 200 includes cut regions (CPOa, CPOb) and power rails (VSS, VDD), each overlapping the respective cut region (CPOa, CPOb), the layout 200 corresponds to a unit cell (e.g., cell C_{T1}, C_{T2}, C_{S}). It is noted, however, that if an additional pair of power rails is present between the power rails (VDD, VSS), the layout 200 is not classified as a unit cell.

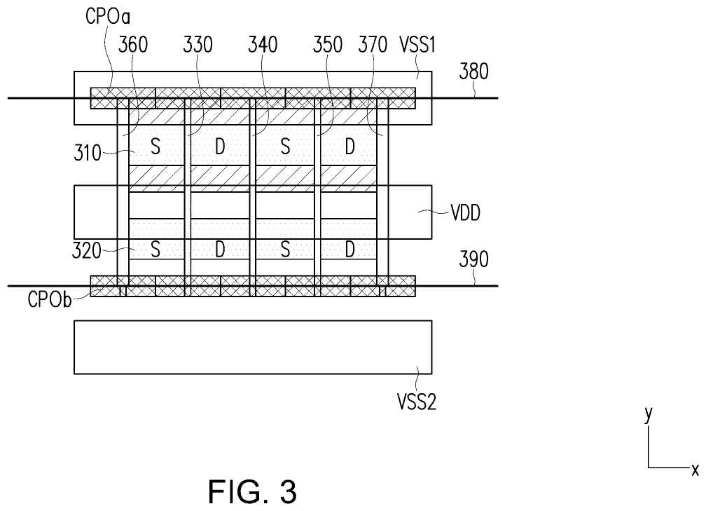

FIG. 3 is a schematic diagram illustrating another exemplary layout in accordance with various embodiments of the present disclosure. In FIG. 3, the example layout 300, or an OHH cell (e.g., OHH cell C_{OHH1}, C_{OHH2}) associated therewith, includes first and second active regions 310, 320, a plurality of gate regions 330-370, source and drain regions (S, D), a pair of cut regions (CPOa, CPOb), and a plurality of power rails (VDD, VSS1, VSS2). The layout 300 is defined by top and bottom boundaries 380, 390, each extending in the first direction (x), and a cell height corresponding to the distance along the second direction (y) between the top and bottom boundaries 280, 290. The first active region 310 extends along the first direction (x) and has a first conductivity type (e.g., p-type). The second active region 320 is substantially parallel to the first active region 310, is spaced apart from the first active region 310 along the second direction (y), and has a second conductivity type (e.g., n-type) different from the first conductivity type. The p-type active region 310 is formed over an n-type well region, while the n-type active region 320 is formed over a p-type well region.

The gate regions 330-350 are functional gate structures (e.g., polysilicon or metal gates) electrically connected to the device. They are responsible for controlling the flow of current between the source and drain regions (S, D) based on an applied voltage. In this exemplary embodiment, each gate region 330-350 extends from the top boundary 380 to the bottom boundary 390 across the active regions 310, 320. The source and drain regions (S, D) are formed in the active regions 310, 320 on opposite sides of the gate region 330-350.

In addition to the gate regions 330-350, the layout 300 further includes non-functional (or dummy) gate regions 360, 370, which may also referred to as dummy gate regions. Dummy gate regions are not electrically connected to (or electrically active in) the one or more circuits of the device. In this exemplary embodiment, each gate region 360, 370 extends from the top boundary 380 to the bottom boundary 390 along the respective edge of the active region 310, 320.

Each cut region (CPOa, CPOb) forms gate regions for different cells. For example, the cut region (CPOa) extends along the top boundary 380 and separates the gate regions 330-370 of the OHH cell 300 from those of one or more adjacent cells above. Similarly, the cut region (CPOb) extends along the bottom boundary 390 and separates the gate regions 330-370 of the unit cell 300 from those of one or more adjacent cells below. In this exemplary embodiment, the cut region (CPOa, CPOb) includes a recess formed in the cell 300 and a dielectric material deposited in the recess.

The power rails (VDD, VSS1, VSS2) each extend in the first direction (x) and are spaced apart from each other in the second direction (y). The power rail (VDD) carries a supply voltage, while the power rail (VSS1, VSS2) carries a reference voltage (e.g., ground or a negative voltage). In certain embodiments, the power rail (VSS1) extends along the boundary 380 and overlaps the cut region (CPOa). The power rail (VDD1) is disposed between the power rails (VSS1, VSS2) and across the gate regions 330-370. The cut region (CPOb) is disposed between the power rails (VDD1, VSS2).

From the description above, because the layout 300 includes cut region (CPOa), a power rail (VSS1) overlapping the cut region (CPOa), power rails (VDD, VSS2), and a cut region (CPOb) between the power rails (VDD, VSS2), the layout 300 corresponds to an OHH cell (e.g., OHH cell C_{OHH1}, C_{OHH2}). It is noted, however, that if an additional pair of power rails is present between the power rails (VDD, VSS1, VSS2), the layout 300 is not classified as an OHH cell.

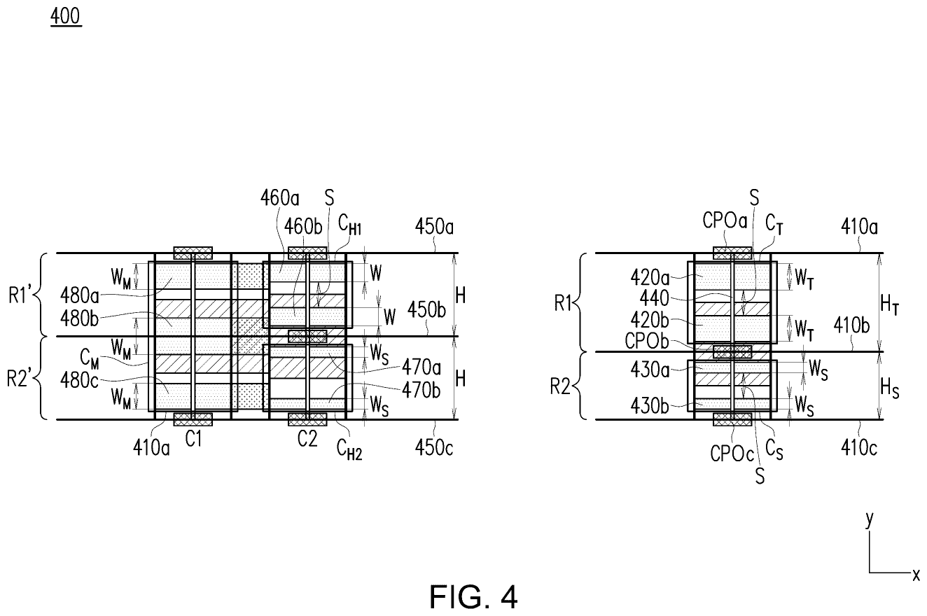

FIG. 4 is a schematic diagram illustrating another exemplary layout in accordance with various embodiments of the present disclosure. In FIG. 4, the example layout 400, or a device associated therewith, includes a plurality of unit cells (C_{T}, C_{S}) that have different heights (H_{T}, H_{S}) and that arranged in an array of rows (R1, R2, R1′, R2′) and columns (C1, C2). Each row (R1, R2) is defined by the boundaries 410a-410c, each extending along the first direction (x), and a row height (H_{T}, H_{S}) corresponding to the distance along the second direction (y) between the boundaries 410a-410c. The unit cell (C_{T}), e.g., a taller cell, is in the first row (R1) and has a cell height that corresponds to the row height (H_{T}). The unit cell (C_{S}), e.g., a shorter cell, is in the second row (R2) and has a cell height that corresponds to the row height (H_{S}). In this exemplary embodiment, the cell height (H_{S}) is smaller than the cell height (H_{T}).

The taller cell (C_{T}) includes first and second active regions 420a, 420b. The first active region 420a extends along the first direction (x) and has a first conductivity type (e.g., p-type). The second active region 420b is substantially parallel to the first active region 420a, is spaced apart from the first active region 420a along the second direction (y), and has a second conductivity type (e.g., n-type) different from the first conductivity type. The p-type active region 420a is formed over an n-type well region, while the n-type active region 420b is formed over a p-type well region.

The shorter cell (C_{S}) includes n- and p-type active regions 430a, 430b. The n-type active region 430a extends along the first direction (x) and is formed over a p-type well region. The p-type active region 430b is substantially parallel to the n-type active region 430a, is spaced apart from the n-type active region 430a along the second direction (y), and is formed over an n-type well region.

In this exemplary embodiment, the active region 430a, 430b has a width (W_{S}) smaller than a width (W_{T}) of the active region 420a, 420b. For example, the ratio of the width (W_{T}) to the width (W_{S}) ranges from about 1.5 to about 2. In certain embodiments, the distance (S) between active regions 430a and 430b is substantially the same as the distance (S) between active regions 420a and 420b.

The layout 400 further includes a gate region 440 and source and drain regions formed in the active regions 420a, 420b, 430a, 430b on opposite sides of the gate region 440. The gate region 440 is a functional gate structure (e.g., polysilicon or metal gates) electrically connected to the device. They are responsible for controlling the flow of current between the source and drain regions based on an applied voltage. In this exemplary embodiment, the gate region 440 extends from the boundary 410a to the boundary 410c through the boundary 410b and across the active regions 420a, 420b, 430a, 430b.

The layout 400 further includes cut regions (CPOa-CPOc), each forming gate regions for different cells (C_{T}, C_{S}). For example, the cut region (CPOa) extends along the boundary 410a and separates the gate region 440 of the tall cell (C_{T}) from those of one or more adjacent cells above.

The cut region (CPOb) extends along the boundary 410b and separates the gate regions 440 of the unit cells (C_{T}, C_{S}) from each other. The cut region (CPOc) extends along the boundary 410c and separates the gate regions 440 of the short cell (C_{S}) from those of one or more adjacent cells below.

The layout 400 further includes a plurality of cells (C_{H1}, C_{H2}, C_{M}) that are arranged in an array of rows (R1′, R2′) and columns (C1, C2). Each row (R1′, R2′) is defined by the boundaries 450a-450c, each extending along the first direction (x), and a row height (H) corresponding to the distance along the second direction (y) between the boundaries 450a-450c. The average height cell (C_{H1}) is in the first row (R1′) and has a cell height that corresponds to the row height (H). The average height cell (C_{H2}) is in the second row (R2′) and has a cell height that corresponds to the row height (H). In this exemplary embodiment, the average height cells (C_{H1}, C_{H2}) have substantially the same cell height (H).

The average height cell (C_{H1}) includes first and second active regions 460a, 460b. The first active region 460a extends along the first direction (x) and has a first conductivity type (e.g., p-type). The second active region 460b is substantially parallel to the first active region 460a, is spaced apart from the first active region 460a along the second direction (y), and has a second conductivity type (e.g., n-type) different from the first conductivity type. The p-type active region 460a is formed over an n-type well region, while the n-type active region 460b is formed over a p-type well region. In this exemplary embodiment, the distance (S) between the active regions 450a, 450b is substantially equal to the distance (S) between the active regions 420a, 420b, 430a, 430b.

The average height cell (C_{H2}) includes n- and p-type active regions 470a, 470b. The n-type active region 470a extends along the first direction (x) and is formed over a p-type well region. The p-type active region 470b is substantially parallel to the n-type active region 470a, is spaced apart from the n-type active region 470a along the second direction (y), and is formed over an n-type well region. In this exemplary embodiment, the active region 470a, 470b has a width (W_{S}) substantially equal to the width (W_{S}) of the active region 470a, 470b and within the range

$$0.3 W \leq {W}_{S} \leq 0.8 W \qquad ( 1 )$$

In this exemplary embodiment, the width (W_{T}) is within the range

$$1.2 W \leq {W}_{T} \leq 2 W \qquad ( 2 )$$

The merged cell (C_{M}) spans the first and second rows (R1′, R2′). For example, the merged cell (C_{M}) has a top edge that aligns with the top edge of the average height cell (C_{H1}) and a bottom edge that aligns with the bottom edge of the average height cell (C_{H2}). In this exemplary embodiment, the merged cell (C_{M}) has a cell height larger than, e.g., substantially twice, the cell height (H).

The merged cell (C_{M}) includes active regions 480a-480c. The first active region 480a extends along the first direction (x) and has a first conductivity type (e.g., p-type). The second active region 480b is substantially parallel to the first active region 480a, is spaced apart from the first active region 480a along the second direction (y), and has a second conductivity type (e.g., n-type) different from the first conductivity type. The third active region 480c is substantially parallel to the second active region 480b, is spaced apart from the second active region 480a along the second direction (y), and has the first conductivity type. In this exemplary embodiment, the active region 480a-480c has a width (WM) within the range

$$1 W \leq {W}_{M} \leq 4 W \qquad ( 3 )$$

In certain embodiments, the width (W_{OHH}) of an OHH cell (e.g., OHH cell C_{OHH1}, C_{OHH2}) is within the range

$$0.4 W \leq {W}_{OHH} \leq 4 W \qquad ( 4 )$$

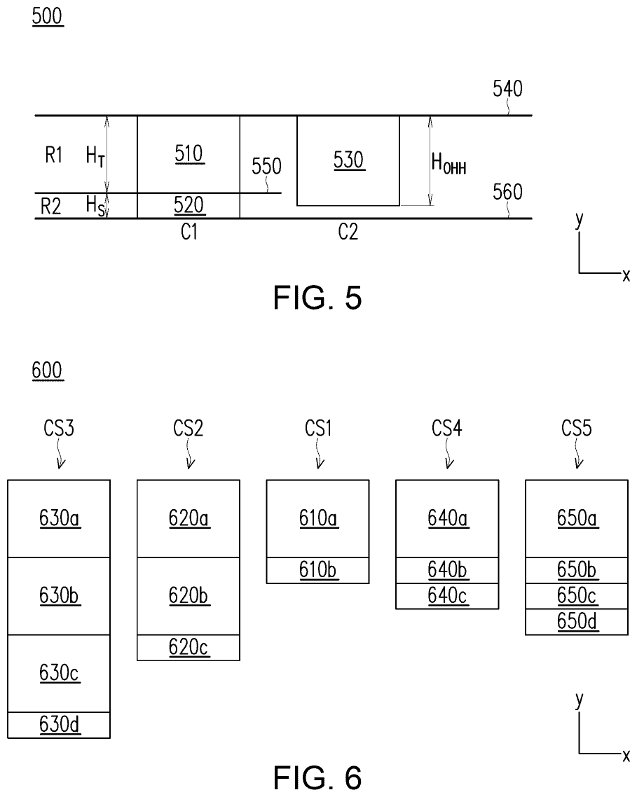

FIG. 5 is a schematic diagram illustrating another exemplary layout in accordance with various embodiments of the present disclosure. In FIG. 5, the example layout 500, or a device associated therewith, includes a plurality of cells 510-530 that have different heights (H_{T}, H_{S}, H_{OHH}) and that arranged in an array of rows (R1, R2) and columns (C1, C2). Each row (R1, R2) is defined by boundaries 540-560, each extending along the first direction (x), and a row height (H_{T}, H_{S}) corresponding to the distance along the second direction (y) between the boundaries 540-560. The first column (C1) includes a pair of unit cells. The unit cell 510, e.g., a taller cell, is in the first row (R1) and has a cell height the corresponds to the row height (H_{T}). The unit cell 520, e.g., a shorter cell, is in the second row (R2) and has a cell height that corresponds to the row height (H_{S}). In this exemplary embodiment, the cell height (H_{S}) is smaller than the cell height (H_{T}).

The third column (C3) includes an OHH cell 530 that spans the first and second rows (R1, R2) and that has a cell height (H_{OHH}) larger than the cell height (H_{T}) of the taller cell 510. In some embodiments, the OHH cell 530 has a top edge that aligns with the top edge of the taller cell 510 and a bottom edge that aligns with the center of the shorter cell 520. In such some embodiments, the OHH cell 450 has a cell height (H_{OHH}) substantially equal to the sum of the cell height (H_{T}) and half the cell height (H_{S}). In other embodiments, the OHH cell 530 has a bottom top edge that aligns with the bottom edge of the shorter cell 520 and a top edge that aligns with the center of the taller cell 510. In such other embodiments, the OHH cell 530 has a cell height (H_{OHH}) substantially equal to the sum of the cell height (H_{S}) and half the cell height (H_{T}).

FIG. 6 is a schematic diagram illustrating another exemplary layout in accordance with various embodiments of the present disclosure. In FIG. 6, the example layout 600, or a device associated therewith, includes a plurality of unit cells 610a-610b, 620a-620c, 630a, 630b, 640a-640c, 650a-650d that have different heights and are arranged in array of rows and columns. In at least one embodiment, the layout 600 includes a plurality of cell structures (CS1-CS5), each including a plurality of unit cells. For example, the unit cells of the cell structure (CS1) include a taller cell 610a in a row and a shorter cell 610b in an adjacent row. The unit cells of the cell structure (CS2) include a pair taller cells 620a, 620b in first two rows, respectively, and a shorter cell 620c in a third row. The unit cells of the cell structure (CS3) include three taller cells 630a-630c in the first three rows, respectively, and a shorter cell 630d in a next row. The unit cells in the cell structure (C4) include a taller cell 640a in a first row (R1) and a pair of shorter cells 640b, 640c in the next two rows. The unit cells of the cell structure (CS5) include a taller cell in a first row (R1) and three shorter cells in the next three rows.

Cell structures (e.g., cell structures CS2, CS3) that have greater number of taller cells than shorter cells are configured for performance, such as speed, whereas cell structures (e.g., cell structures CS4, CS5) that have greater number of shorter cells than taller cells are configured for power and area. For example, the number of tall and shorter cells determines the applicability of a cell structure to improve either performance or power and area. In certain embodiments, such applicability is represented by an equivalent cell height (H_{E}) of a cell structure. For example, the equivalent cell height (H_{E}) is determined as follows:

$${R}_{MIX} = \frac{number of taller cells}{number of shorter cells} \qquad ( 5 )$$

$${H}_{E} = \frac{{H}_{T} {R}_{mix} + {H}_{S}}{{R}_{mix} + 1} \qquad ( 6 )$$

In an example, for the cell structure (CS3), R_{MIX}=3 and H_{E}=(3H_{T}+H_{S})/4. In another example, for the cell structure (CS5), R_{MIX}=1/3 and H_{E}=(H_{T}+3H_{S})/4. That is, each R_{MIX} and H_{E} increases toward the cell structure (CS3) and decreases toward the cell structure (CS5). The cell structure (CS1) has R_{MIX}=1 and and H_{E}=(H_{T}+H_{S})/2. In at least one embodiment, H_{T}+H_{S}=2H, resulting in the cell structure (CS1) having H_{E}=H. This indicates that cell structures with cells of the same height (H) is comparable in terms of performance and power/area to cell columns with cells of varying heights (H_{T}, H_{S}). For example, when H_{E} is greater than H, the cell structure (CS2, CS3) provides performance improvements over the cell structure with cells having the same height. As such, the cell structure (CS2, CS3) is applicable to speed-oriented applications. Between the cell structures (CS2, CS3), the cell structure (CS2) provides smaller performance improvements, but have better power and area parameters, than the cell structure (CS3).

On the other hand, when H_{E} is less than H, the cell structure (CS4, CS5) provides power and area improvements over the cell structure with cells having the same height. Between the cell structures (CS4, CS5), the cell structure (C4) provides smaller power and area improvements, but have better performance (i.e., higher speed), than the cell structure (CS5).

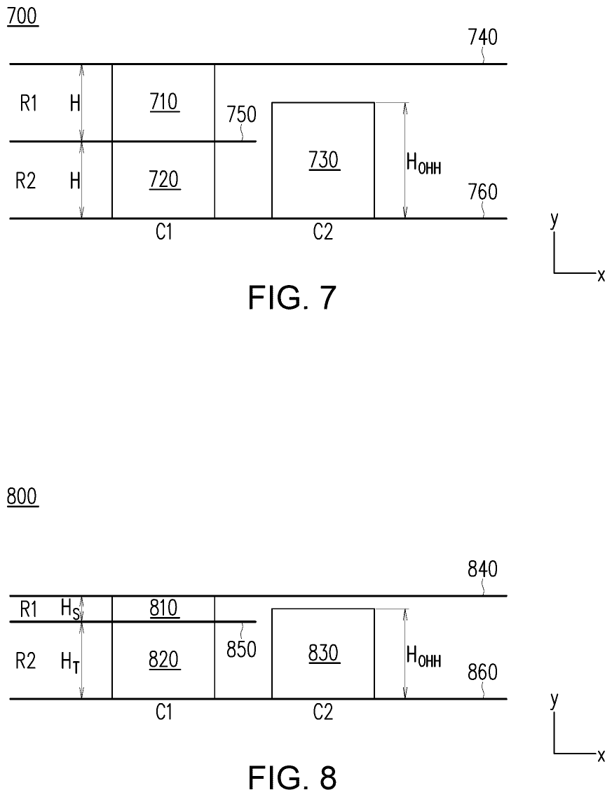

In certain embodiments, an OHH cell is defined by a cell height substantially equal to the sum of a cell height of a unit cell and half the cell height of another unit cell in an adjacent row. In an example, FIG. 7 is a schematic diagram illustrating another exemplary layout in accordance with various embodiments of the present disclosure. As illustrated in FIG. 7, the example layout 700, or a device associated therewith, includes a plurality of cells 710-730 that have different heights (H, H_{OHH}) and that are arranged in an array of rows (R1, R2) and columns (C1, C2). The rows (R1, R2) are defined by boundaries 740-760, each extending along the first direction (x), and a row height (H) corresponding to the distance along the second direction (y) between the boundaries 740-760. The first column (C1) includes a pair of average height cells 710, 720. Each average height cell 710, 720 has a cell height that corresponds to the row height (H).

The second column (C2) includes an OHH cell 730 that spans the first and second rows (R1, R2) and has a cell height (H_{OHH}) larger than the cell height (H). In at least one embodiment, the OHH cell 730 has a bottom edge that aligns with the bottom edge of the average height cell 720 and a top edge that aligns with the center of the average height cell 710. In such at least one embodiment, the OHH cell 730 has a cell height (H_{OHH}) substantially equal to the sum of the cell height (H) of the average height cell 720 and half the cell height (H) of the average height cell 710.

In another example, FIG. 8 is a schematic diagram illustrating another exemplary layout in accordance with various embodiments of the present disclosure. As illustrated in FIG. 8, the example layout 800, or a device associated therewith, includes a plurality of cells 810-830 that have different heights (H_{T}, H_{S}, H_{OHH}) and that are arranged in array of rows (R1, R2) and columns (C1, C2). The rows (R1, R2) are defined by boundaries 840-860, each extending along the first direction (x), and a row height (H_{S}, H_{T}) corresponding to the distance along the second direction (y) between the boundaries 840, 850. The first column (C1) includes a pair of unit cells, i.e., a shorter cell 810 in the first row (R1) and a taller cell 820 in the second row (R2). Each unit cell 810, 820 has a cell height that corresponds to the respective row height (H_{S}, H_{T}). In this exemplary embodiment, the cell height (H_{S}) is smaller than the cell height (H_{T}).

The second column (C2) includes an OHH cell 830 that spans the first and second rows (R1, R2) and that has a cell height (H_{OHH}) larger than the cell height (H_{T}). In at least one embodiment, the OHH cell 830 has a bottom edge that aligns with the bottom edge of the taller cell 820 and a top edge that aligns with the center of the shorter cell 810. In such at least one embodiment, the OHH cell 730 has a cell height (H_{OHH}) substantially equal to the sum of the cell height (H_{T}) and half the cell height (H_{S}).

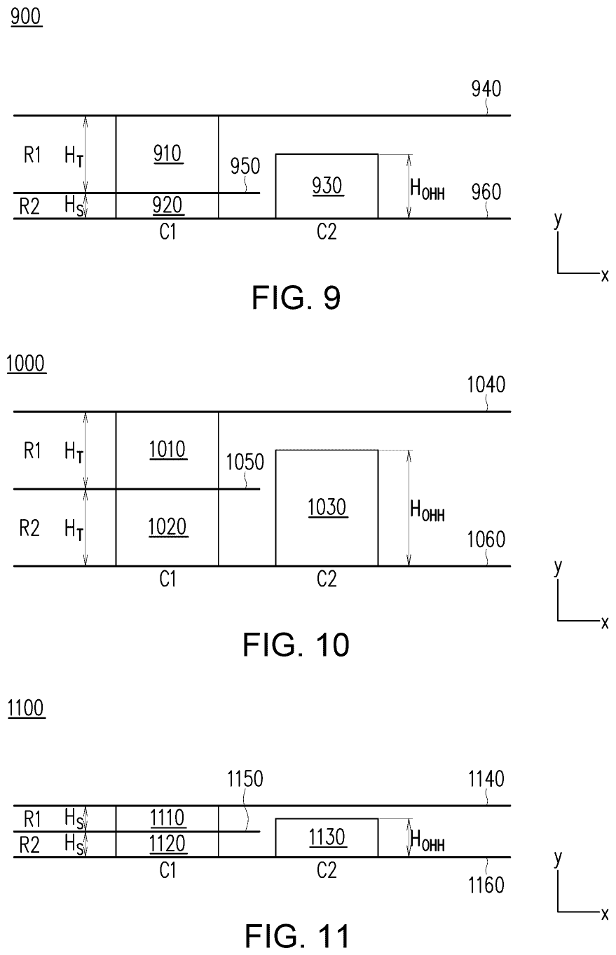

In another example, FIG. 9 is a schematic diagram illustrating another exemplary layout in accordance with various embodiments of the present disclosure. As illustrated in FIG. 9, the example layout 900, or a device associated therewith, includes a plurality of units cells 910-930 that have different heights (H_{T}, H_{S}, H_{OHH}) and that are arranged in array of rows (R1, R2) and columns (C1, C2). The rows (R1, R2) are defined by boundaries 940-960, each extending along the first direction (x), and a row height (H_{S}, H_{T}) corresponding to the distance along the second direction (y) between the boundaries 940-960. The first column (C1) includes a pair of unit cells, i.e., a taller cell 910 and a shorter cell 920. Each unit cell 910, 920 has a cell height that corresponds to the respective row height (H_{T}, H_{S}). In this exemplary embodiment, the cell height (H_{S}) is smaller than the cell height (H_{T}).

The second column (C2) includes an OHH cell 930 that spans the first and second rows (R1, R2) and that has a cell height (H_{OHH}) larger than the cell height (H_{T}). In at least one embodiment, the OHH cell 930 has a bottom edge that aligns with the bottom edge of the shorter cell 920 and a top edge that aligns with the center of the taller cell 910. In such at least one embodiment, the OHH cell 930 has a cell height (H_{OHH}) substantially equal to the sum of the cell height (H_{S}) and half the cell height (H_{T}).

In another example, FIG. 10 is a schematic diagram illustrating another exemplary layout in accordance with various embodiments of the present disclosure. As illustrated in FIG. 10, the example layout 1000, or a device associated therewith, includes a plurality of cells 1010-1030 that have different heights (H_{T}, H_{OHH}) and that are arranged in an array of rows (R1, R2) and columns (C1, C2). The rows (R1, R2) are defined by boundaries 1040-1060, each extending along the first direction (x), and a row height (H_{T}) corresponding to the distance along the second direction (y) between the boundaries 1040-1060. The first column (C1) includes a pair of unit cells 1010, 1020, e.g., two taller cells. Each unit cell 1010, 1020 has a cell height that corresponds to the row height (H_{T}).

The second column (C2) includes an OHH cell 1030 that extends between the first and second rows (R1, R2) and has a cell height (H_{OHH}) larger than the cell height (H_{T}). In at least one embodiment, the OHH cell 1030 has a bottom edge that aligns with the bottom edge of the taller cell 1020 and a top edge that aligns with the center of the taller cell 1010. In such at least one embodiment, the OHH cell 1030 has a cell height (H_{OHH}) substantially equal to the sum of the cell height (H_{T}) of the taller cell 1020 and half the cell height (H_{T}) of the taller cell 1010.

In another example, FIG. 11 is a schematic diagram illustrating another exemplary layout in accordance with various embodiments of the present disclosure. As illustrated in FIG. 11, the example layout 1100, or a device associated therewith, includes a plurality of cells 1110-1130 that have different heights (H_{S}, H_{OHH}) and that are arranged in an array of rows (R1, R2) and columns (C1, C2). The rows (R1, R2) are defined by boundaries 1140-1160, each extending along the first direction (x), and a row height (H_{S}) corresponding to the distance along the second direction (y) between the boundaries 1140-1160. The first column (C1) includes a pair of unit cells 1110, 1120, e.g., two shorter cells. Each unit cell 1110, 1120 has a cell height that corresponds to the row height (H_{S}).

The second column (C2) includes an OHH cell 1130 that extends between the first and second rows (R1, R2) and has a cell height (H_{OHH}) larger than the cell height (H_{S}). In at least one embodiment, the OHH cell 1130 has a bottom edge that aligns with the bottom edge of the shorter cell 1120 and a top edge that aligns with the center of the shorter cell 1110. In such at least one embodiment, the OHH cell 1130 has a cell height (H_{OHH}) substantially equal to the sum of the cell height (H_{S}) of the shorter cell 1120 and half the cell height (H_{S}) of the shorter cell 1110.

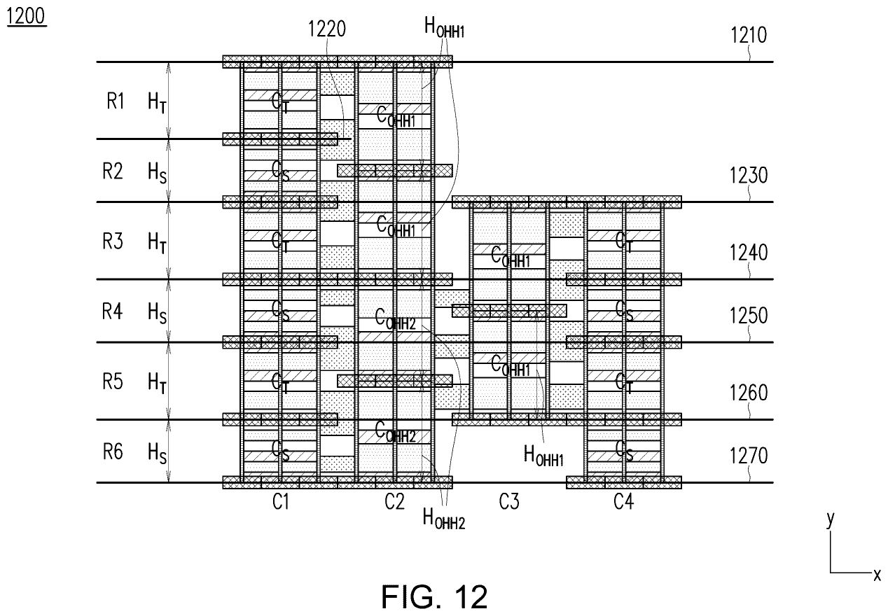

FIG. 12 is a schematic diagram illustrating another exemplary layout in accordance with various embodiments of the present disclosure. In FIG. 12, the example layout 1300, or a device associated therewith, includes a plurality of cells (C_{T}, C_{S}, C_{OHH1}, C_{OHH2}) that have different heights (H_{T}, H_{S}, H_{OHH1}, H_{OHH2}) and that are arranged in an array of rows (R1-R6) and columns (C₁-C₄). The first column (C1) includes a plurality of unit cells, e.g., taller and shorter cells (C_{T}, C_{S}). In certain embodiments, the taller and shorter cells (C_{T}, C_{S}) alternate across the rows (R1-R6). In this exemplary embodiment, the taller cell (C_{T}) has a cell height (H_{T}), while the shorter cell (C_{S}) has a cell height (H_{S}) smaller than the cell height (H_{T}).

The second column (C2) includes a pair of OHH cells (C_{OHH1}) and a pair of OHH cells (C_{OHH2}). Each OHH cell (C_{OHH1}, C_{OHH2}) spans an adjacent pair of rows. For example, the first OHH cell (C_{OHH1}) has a top edge that aligns with the top edge of the taller cell (C_{T}) in the first row (R1) and a bottom edge that aligns with the center of the shorter cell (C_{S}) in the second row (R2). The second OHH cell (C_{OHH1}) has a bottom edge that aligns with the bottom edge of the taller cell (C_{T}) in the third row (R3) and a top edge that aligns with the center of the shorter cell (C_{S}) in the second row (R2). In this exemplary embodiment, the OHH cell (C_{OHH1}, C_{OHH2}) has a cell height (H_{OHH1}) substantially equal to the sum of the cell height (H_{T}) and half the cell height (H_{S}). In this exemplary embodiment, the OHH cell (C_{OHH1}) has a cell height (H_{OHH1}) substantially equal to the sum of the cell height (H_{T}) and half the cell height (H_{S}).

Similarly, the first OHH cell (C_{OHH2}) has a top edge that aligns with the top edge of the shorter cell (C_{S}) in the fourth row (R4) and a top edge that aligns with the center of the taller cell (C_{T}) in the fifth row (R5). The second OHH cell (C_{OHH2}) has a bottom edge that aligns with the bottom edge of the shorter cell (C_{S}) in the sixth row (R6) and a top edge that aligns with the center of the tall cell (C_{T}) in the fifth row (R5). In certain embodiments, the OHH cell (C_{OHH2}) has a cell height (H_{OHH2}) substantially equal to the sum of the cell height (H_{S}) and half the cell height (H_{T}). In such certain embodiments, the cell height (H_{OHH2}) is smaller than the cell height (H_{OHH1}).

The third column (C2) includes a pair of OHH cells (C_{OHH1}). Each OHH cell (C_{OHH1}) spans an adjacent pair of rows and has a cell height (H_{OHH1}) larger than the cell height (H_{T}). For example, the first OHH cell (C_{OHH1}) has a top edge that aligns with the top edge of the taller cell (C_{T}) in the third row (R3) and a bottom edge that aligns with the center of the shorter cell (C_{S}) in the fourth row (R2). The second OHH cell (C_{OHH1}) has a bottom edge that aligns with the bottom edge of the taller cell (C_{T}) in the fifth row (R5) and a top edge that aligns with the center of the shorter cell (C_{S}) in the fourth row (R4). In this exemplary embodiment, the OHH cell (C_{OHH1}) has a cell height (H_{OHH1}) substantially equal to the sum of the cell height (H_{T}) and half the cell height (H_{S}).

The fourth column (C4) includes a plurality of unit cells, e.g., taller and shorter cells (C_{T}, C_{S}). In certain embodiments, the taller and shorter cells (C_{T}, C_{S}) alternate across the rows (R3-R6). In this exemplary embodiment, the taller cell (C_{T}) has a cell height (H_{T}), while the shorter cell (C_{S}) has a cell height (H_{S}) smaller than the cell height (H_{T}).

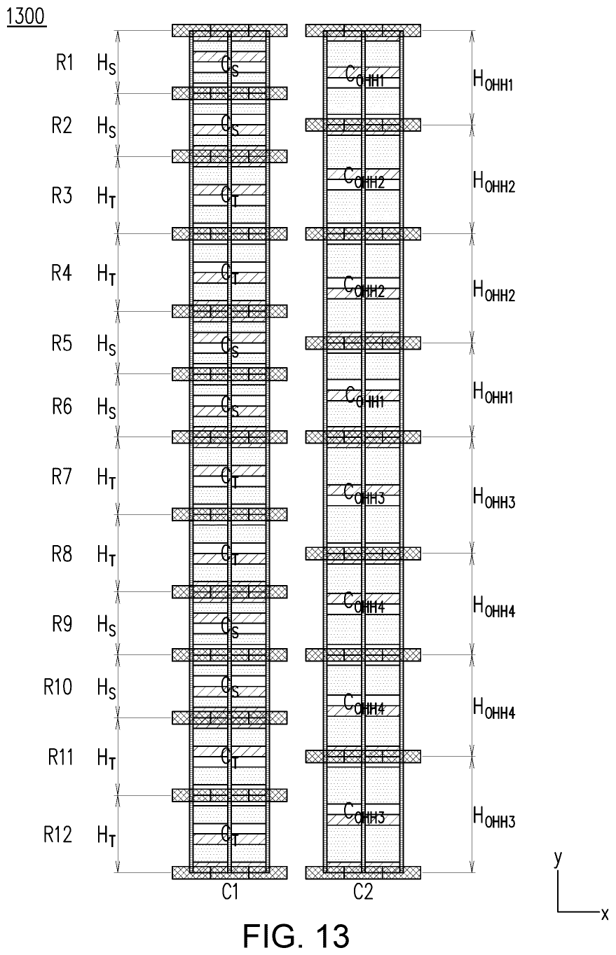

FIG. 13 is a schematic diagram illustrating another exemplary layout in accordance with various embodiments of the present disclosure. In FIG. 13, the example layout 1300, or a device associated therewith, includes a plurality of cells (C_{T}, C_{S}, C_{OHH1}, C_{OHH2}, C_{OHH3}, C_{OHH4}) that have different heights (H_{T}, H_{S}, H_{OHH1}, H_{OHH2}, H_{OHH3}, H_{OHH4}) and that are arranged in an array of rows (R1-R12) and columns (C1, C2). The first column (C1) includes a plurality of unit cells, e.g., taller and shorter cells (C_{T}, C_{S}). In certain embodiments, adjacent pairs of taller and shorter cells (C_{T}, C_{S}) alternate across the rows (R1-R6). In this exemplary embodiment, the taller cell (C_{T}) has a cell height (H_{T}), while the shorter cell (C_{S}) has a cell height (H_{S}) smaller than the cell height (H_{T}).

The second column (C2) includes a pair of OHH cells (C_{OHH1}), a pair of OHH cells (C_{OHH2}), a pair of OHH cells (C_{OHH3}), a pair of OHH cells (C_{OHH4}). Each OHH cell (C_{OHH1}, C_{OHH2}, C_{OHH3}, C_{OHH4}) spans an adjacent pair of rows. For example, the first OHH cell (C_{OHH1}) has a top edge that aligns with the top edge of the shorter cell (C_{S}) in the first row (R1) and a bottom edge that aligns with the center of the shorter cell (C_{S}) in the second row (R2). The first OHH cell (C_{OHH2}) has a bottom edge that aligns with the bottom edge of the taller cell (C_{T}) in the third row (R3) and a top edge that aligns with the center of the shorter cell (C_{S}) in the second row (R2).

The second OHH cell (C_{OHH2}) has a top edge that aligns with the top edge of the taller cell (C_{T}) in the fourth row (R4) and a bottom edge that aligns with the center of the shorter cell (C_{S}) in the fifth row (R5). The second OHH cell (C_{OHH1}) has a bottom edge that aligns with the bottom edge of the shorter cell (C_{S}) in the sixth row (R6) and a top edge that aligns with the center of the shorter cell (C_{S}) in the fifth row (R5).

Similarly, the first OHH cell (C_{OHH3}) has a top edge that aligns with the top edge of the taller cell (C_{T}) in the seventh row (R7) and a bottom edge that aligns with the center of the taller cell (C_{T}) in the eighth row (R8). The first OHH cell (C_{OHH4}) has a bottom edge that aligns with the bottom edge of the shorter cell (C_{S}) in the ninth row (R9) and a top edge that aligns with the center of the taller cell (C_{T}) in the eighth row (R8).

The second OHH cell (C_{OHH4}) has a top edge that aligns with the top edge of the shorter cell (C_{S}) in the tenth row (R10) and a bottom edge that aligns with the center of the taller cell (C_{T}) in the eleventh row (R11). The second OHH cell (C_{OHH3}) has a bottom edge that aligns with the bottom edge of the taller cell (C_{T}) in the twelfth row (R12) and a top edge that aligns with the center of the taller cell (C_{T}) in the eleventh row (R11).

In certain embodiments, the OHH cell (C_{OHH1}) has a cell height (H_{OHH1}) substantially equal to the sum of the cell height (H_{S}) and half the cell height (H_{S}). The OHH cell (C_{OHH2}) has a cell height (H_{OHH2}) substantially equal to the sum of the cell height (H_{T}) and half the cell height (H_{S}). The OHH cell (C_{OHH3}) has a cell height (H_{OHH3}) Substantially equal to the sum of the cell height (H_{T}) and half the cell height (H_{T}). The OHH cell (C_{OHH4}) has a cell height (H_{OHH3}) substantially equal to the sum of the cell height (H_{S}) and half the cell height (H_{T}).

In such certain embodiments, the following relationship is satisfied

$$H s < {H}_{T} < {H}_{OHH 1} < {H}_{OHH 4} < {H}_{OHH 2} < {H}_{OHH 3} \qquad ( 7 )$$

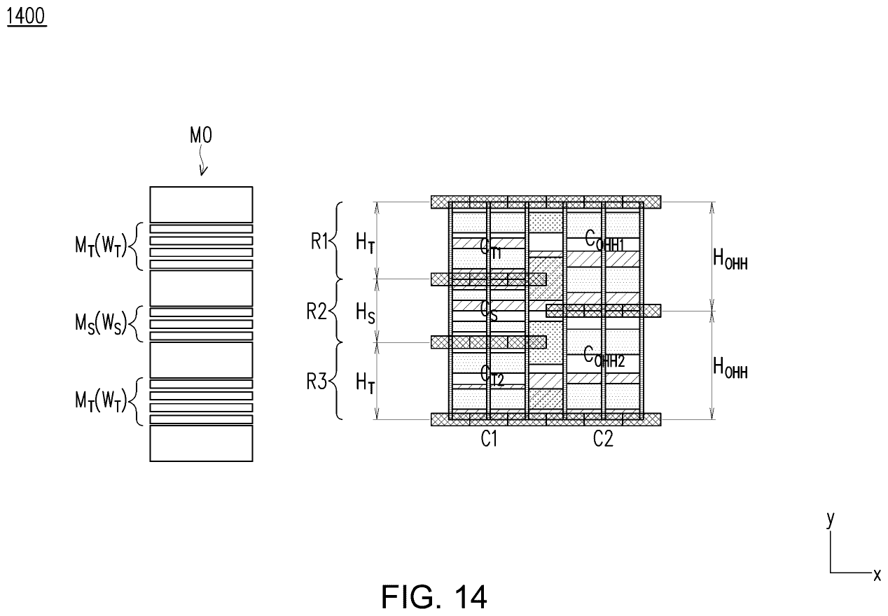

FIG. 14 is a schematic diagram illustrating another exemplary layout in accordance with various embodiments of the present disclosure. In FIG. 14, the example layout 1400, or a device associated therewith, includes a plurality of cells (C_{T1}, C_{T2}, C_{S}, C_{OHH1}, C_{OHH2}) that have different cell heights (H_{T}, H_{S}, H_{OHH}) and that are arranged in an array of rows (R1-R3) and columns (C1, C2). The first column (C1) includes a plurality of unit cells, e.g., a pair of taller cells (C_{T1}, C_{T2}) and a shorter cell (C_{S}) between the taller cells (C_{T1}, C_{T2}). In this exemplary embodiment, the taller cell (C_{T1}, C_{T2}) has a cell height (H_{T}), while the shorter cell (C_{S}) has a cell height (H_{S}) smaller than the cell height (H_{T}).

The second column (C2) includes a pair of OHH cells (C_{OHH1}, C_{OHH1}), each overlapping an adjacent pair of rows. For example, the OHH cell (C_{OHH1}) has a top edge that aligns with the top edge of the taller cell (C_{T1}) and a bottom edge that aligns with the center of the shorter cell (C_{S}). Similarly, the OHH cell (C_{OHH2}) has a bottom edge that aligns with the bottom edge of the taller cell (C_{T2}) and a bottom edge that aligns with the center of the shorter cell (C_{S}). In this exemplary embodiment, the OHH cell (C_{OHH1}, C_{OHH2}) has a cell height (H_{OHH}) substantially equal to the sum of the cell height (H_{T}) and half the cell height (H_{S}).

The layout further includes a plurality of metal layer (M0) disposed between the cells (C_{T1}, C_{T2}, C_{S}, C_{OHH1}, C_{OHH2}) and the power rails (e.g., power rails VDD, VSS). The metal layer (M0) may correspond to the first metal layer in a metal stack. In at least one embodiment, the metal layer (M0) includes large, medium, small width metal lines (M_{H}, M_{T}, M_{S}). The metal line (M_{H}) connects cells (e.g., average height cells 710, 720) of a column that have the same height across a row to the power rails (VDD, VSS) and facilitates signal routing between the average height cells 710, 720. The metal line (M_{T}) connects the unit cells (e.g., taller cells C_{T1}, C_{T2}) to the power rails (VDD, VSS) and facilitates signal routing between the taller cells (C_{T1}, C_{T2},). The metal line (M_{S}) connects the unit cells (e.g., shorter cells C_{S}) to the power rails (VDD, VSS) and facilitates signal routing between the shorter cells (C_{S}). In this exemplary embodiment, the metal line (M_{H}) has a width smaller than the width of the metal line (M_{T}) and larger than the width of the metal line (M_{S}). This strategic variation in metal line widths of the metal layer (M0) also contributes to achieving an overall optimal PPA for the device of the present disclosure.

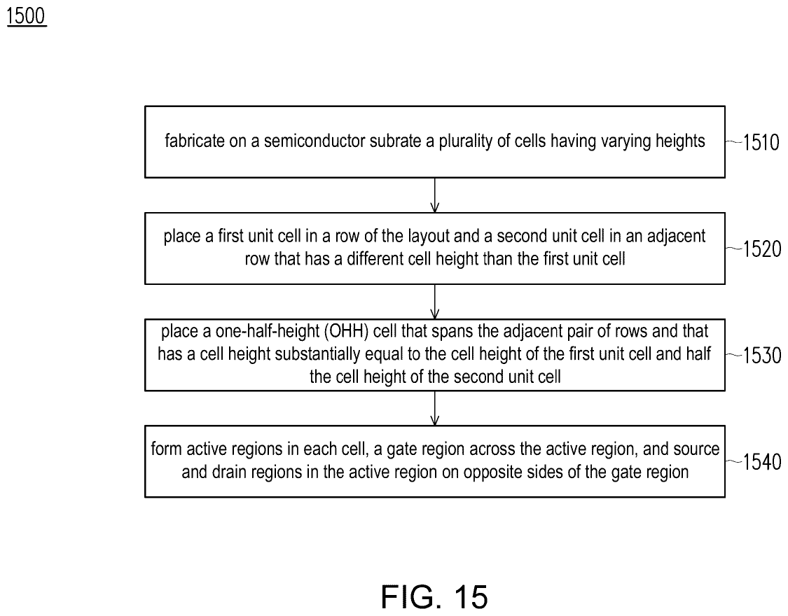

FIG. 15 is a flowchart of an exemplary method of manufacturing a device in accordance with various embodiments of the present disclosure. The example method 1500 will now be described with further reference to FIGS. 1-14 for ease of understanding. It is understood that method 1500 is applicable to structures other than those of FIGS. 1-14. Further, it is understood that additional operations can be provided before, during, and after the method 1500, and some of the operations described below can be replaced or eliminated, in an alternative embodiment of the method 1500.

In operation 1510, the device manufacturing system places in a layout a plurality of unit cells in a first column (C1) across rows (R1-R3). The unit cells includes a taller cell (C_{T1}) in the first row (R1), a shorter cell (C_{S}) in a second row (R2), and another taller cell (C_{T2}) in the third row (R3). In operation 1520, the device manufacturing system places in the layout one or more OHH cells (C_{OHH1}, C_{OHH2}) in a second column. For example, the first OHH cell (C_{OHH1}) spans the first and second rows (R1, R2), while the first OHH cell (C_{OHH2}) spans the second and third rows (R2, R3). In operation 1530, the device manufacturing system places in the layout a plurality of active regions in each cell (C_{T1}, C_{T2}, C_{S}, C_{OHH1}, C_{OHH2}). In operation 1540, the device manufacturing system places in the layout a gate regions across the active region. In operation 1550, the device manufacturing system places in the layout source and drain regions in the active region on opposite sides of the gate region. In operation 1560, the device manufacturing system fabricates a device using the layout.

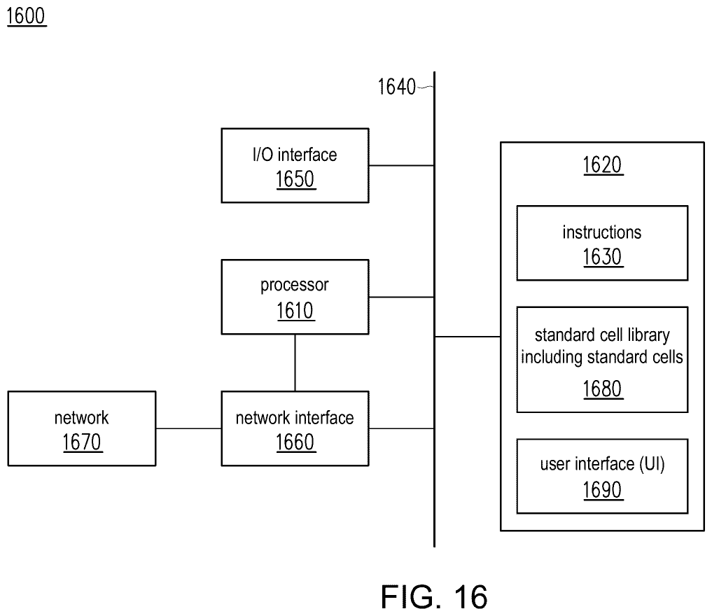

FIG. 16 is schematic block diagram of an exemplary electronic design automation (EDA) system 1600 in accordance with various embodiments of the present disclosure. In FIG. 16, the example EDA system 1600 includes an automated placement and routing (APR) system. Methods described herein of designing layout diagrams represent wire routing arrangements, in accordance with one or more embodiments, are implementable, for example, using the EDA system 1600.

In at least one embodiment, the EDA system 1600 is a general purpose computing device including a hardware processor 1610 and a non-transitory, computer-readable storage medium 1620. The computer-readable storage medium 1620, amongst other things, is encoded with, i.e., stores, computer program code 1630, i.e., a set of executable instructions. Execution of instructions 1630 by hardware processor 1610 represents (at least in part) an EDA tool which implements a portion or all of the methods described herein in accordance with one or more embodiments (hereinafter, the noted processes and/or methods).

The processor 1610 is electrically coupled to the computer-readable storage medium 1620 via a bus 1640. Processor 1610 is also electrically coupled to an I/O interface 1650 by the bus 1640. A network interface 1660 is also electrically connected to the processor 1610 via the bus 1640. The network interface 1660 is connected to a network 1670, so that the processor 1610 and the computer-readable storage medium 1620 are capable of connecting to external elements via the network 1670. The processor 1610 is configured to execute computer program code 1630 encoded in the computer-readable storage medium 1620 in order to cause the system 1600 to be usable for performing a portion or all of the noted processes and/or methods. In one or more embodiments, the processor 1610 is a central processing unit (CPU), a multi-processor, a distributed processing system, an application specific integrated circuit (ASIC), and/or a suitable processing unit.

In at least one embodiments, the computer-readable storage medium 1620 is an electronic, magnetic, optical, electromagnetic, infrared, and/or a semiconductor system (or apparatus or device). For example, the computer-readable storage medium 1620 includes a semiconductor or solid-state memory, a magnetic tape, a removable computer diskette, a random access memory (RAM), a read-only memory (ROM), a rigid magnetic disk, and/or an optical disk. In certain embodiments using optical disks, the computer-readable storage medium 1620 includes a compact disk-read only memory (CD-ROM), a compact disk-read/write (CD-R/W), and/or a digital video disc (DVD).

In this exemplary embodiment, the computer-readable storage medium 1620 stores computer program code 1630 configured to cause system 1600 (where such execution represents, at least in part, the EDA tool) to be usable for performing a portion or all of the noted processes and/or methods. In an embodiment, the computer-readable storage medium 1620 also stores information which facilitates performing a portion or all of the noted processes and/or methods. In such an embodiment, the computer-readable storage medium 1620 stores library 1680 of standard cells including such standard cells as disclosed herein.

The I/O interface 1650 is coupled to external circuitry. In certain embodiments, the I/O interface 1650 includes a keyboard, keypad, mouse, trackball, trackpad, touchscreen, and/or cursor direction keys for communicating information and commands to the processor 1610.

The network interface 1660 is coupled to the processor 1610. The network interface 1660 allows the system 1600 to communicate with the network 1670, to which one or more other computer systems are connected. The network interface 1660 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1600.

The system 1600 is configured to receive information through the I/O interface 1650. The information received through the I/O interface 1650 includes one or more of instructions, data, design rules, libraries of standard cells, and/or other parameters for processing by the processor 1302. The information is transferred to the processor 1610 via the bus 1640. The EDA system 1600 is configured to receive information related to a UI through the I/O interface 1650. The information is stored in the computer-readable storage medium 1620 as a user interface (UI) 1690.

In some embodiments, a portion or all of the noted processes and/or methods is implemented as a standalone software application for execution by a processor. In other embodiments, a portion or all of the noted processes and/or methods is implemented as a software application that is a part of an additional software application. In certain embodiments, a portion or all of the noted processes and/or methods is implemented as a plug-in to a software application. In one embodiment, at least one of the noted processes and/or methods is implemented as a software application that is a portion of an EDA tool. In one or more embodiments, a portion or all of the noted processes and/or methods is implemented as a software application that is used by the EDA system 1600. In at least one embodiment, a layout diagram which includes standard cells is generated using a tool such as VIRTUOSO@available from CADENCE DESIGN SYSTEMS, Inc., or another suitable layout generating tool.

In one embodiment, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

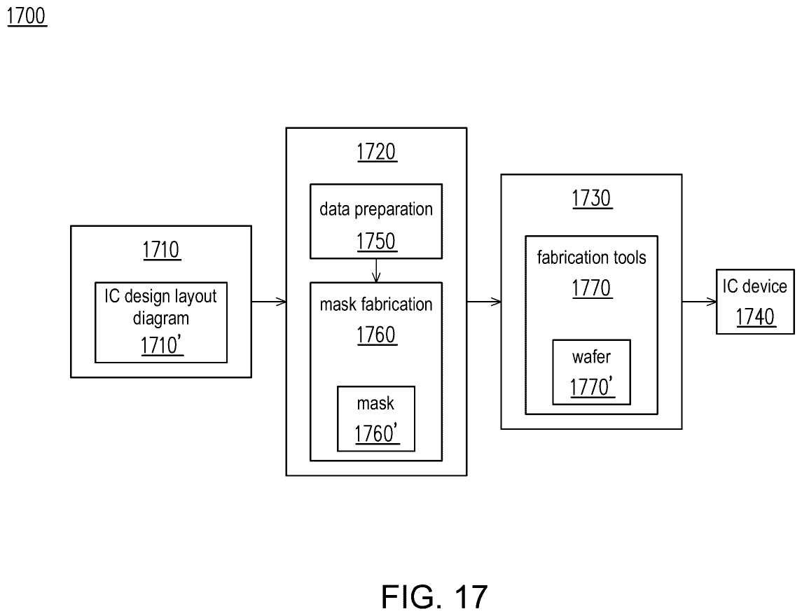

FIG. 17 is a schematic block diagram of an exemplary integrated circuit (IC) manufacturing system 1700 in accordance with various embodiments. In at least one embodiment, based on a layout diagram, at least one of one or more semiconductor masks or at least one component in a layer of a semiconductor integrated circuit is fabricated using the manufacturing system 1700. In FIG. 14, the example IC manufacturing system 1700 includes entities, such as a design house 1710, a mask house 1720, and an IC manufacturer/fabricator (or fab) 1730, that interact with one another in the design, development, and manufacturing cycles and/or services related to manufacturing an IC device 1740. The entities in system 1700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In certain embodiments, two or more of design house 1710, mask house 1720, and IC fab 1730 is owned by a single larger company. In other embodiments, two or more of design house 1710, mask house 1720, and IC fab 1730 coexist in a common facility and use common resources.

Design house (or design team) 1710 generates an IC design layout diagram 1710′. IC design layout diagram 1710′ includes various geometrical patterns designed for an IC device 1740. The geometrical patterns correspond to patterns of metal, oxide, or semiconductor layers that make up the various components of IC device 1740 to be fabricated. The various layers combine to form various IC features. For example, a portion of IC design layout diagram 1710′ includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1710 implements a proper design procedure to form IC design layout diagram 1710′. The design procedure includes one or more of logic design, physical design or place-and-route operation. IC design layout diagram 1710 is presented in one or more data files having information of the geometrical patterns. For example, IC design layout diagram 1710′ can be expressed in a GDSII file format or DFII file format.

Mask house 1720 includes data preparation 1750 and mask fabrication 1760. Mask house 1720 uses IC design layout diagram 1710′ to manufacture one or more masks 1760′ to be used for fabricating the various layers of IC device 1740 according to IC design layout diagram 1710′. Mask house 1720 performs mask data preparation 1750, where IC design layout diagram 1710′ is translated into a representative data file (“RDF”). Mask data preparation 1750 provides the RDF to mask fabrication 1760. Mask fabrication 1760 includes a mask writer. A mask writer converts the RDF to an image on a substrate, such as a mask (reticle) 1760′ or a semiconductor wafer 1770′. The design layout diagram 1710′ is manipulated by mask data preparation 1750 to comply with particular characteristics of the mask writer and/or requirements of IC fab 1730. Mask data preparation 1750 and mask fabrication 1760 are illustrated in FIG. 17 as separate elements. In some embodiments, mask data preparation 1750 and mask fabrication 1760 can be collectively referred to as mask data preparation.

In some embodiments, mask data preparation 1750 includes optical proximity correction (OPC) which uses lithography enhancement techniques to compensate for image errors, such as those that can arise from diffraction, interference, other process effects and the like. OPC adjusts IC design layout diagram 1710′. In at least one embodiment, mask data preparation 1750 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In certain embodiments, mask data preparation 1750 includes a mask rule checker (MRC) that checks the IC design layout diagram 1710′ that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1710′ to compensate for limitations during mask fabrication 1760, which may undo part of the modifications performed by OPC in order to meet mask creation rules.

In one or more embodiments, mask data preparation 1750 includes lithography process checking (LPC) that simulates processing that will be implemented by IC fab 1730 to fabricate IC device 1740. LPC simulates this processing based on IC design layout diagram 1710′ to create a simulated manufactured device, such as IC device 1740. The processing parameters in LPC simulation can include parameters associated with various processes of the IC manufacturing cycle, parameters associated with tools used for manufacturing the IC device 1740, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1710′.

It should be understood that the above description of mask data preparation 1750 has been simplified for the purposes of clarity. In some embodiments, data preparation 1750 includes additional features such as a logic operation (LOP) to modify the IC design layout diagram 1710′ according to manufacturing rules. Additionally, the processes applied to IC design layout diagram 1710′ during data preparation 1750 may be executed in a variety of different orders.

After mask data preparation 1750 and during mask fabrication 1760, a mask 1760′ or a group of masks 1760′ are fabricated based on the modified IC design layout diagram 1710′. In some embodiments, mask fabrication 1760 includes performing one or more lithographic exposures based on IC design layout diagram 1710′. In other embodiments, an electron-beam (e-beam) or a mechanism of multiple e-beams is used to form a pattern on a mask (photomask or reticle) 1760′ based on the modified IC design layout diagram 1710′. Mask 1760′ can be formed in various technologies. In an embodiment, mask 1760′ is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1760′ includes a transparent substrate (e.g., fused quartz) and an opaque material (e.g., chromium) coated in the opaque regions of the binary mask. In another example, mask 1760′ is formed using a phase shift technology. In a phase shift mask (PSM) version of mask 1760′, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1760 is used in a variety of processes. For example, such a mask(s) is used in an ion implantation process to form various doped regions in semiconductor wafer 1770′, in an etching process to form various etching regions in semiconductor wafer 1770′, and/or in other suitable processes.

IC fab 1730 is an IC fabrication business that includes one or more manufacturing facilities for the fabrication of a variety of different IC products. In some embodiments, IC fab 1730 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1730 includes fabrication tools 1770 configured to execute various manufacturing operations on semiconductor wafer 1770′ such that IC device 1740 is fabricated in accordance with the mask(s), e.g., mask 1760′. In various embodiments, fabrication tools 1770 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1730 uses mask(s) 1760′ fabricated by mask house 1720 to fabricate IC device 1740. Thus, IC fab 1730 at least indirectly uses IC design layout diagram 1710′ to fabricate IC device 1740. In some embodiments, semiconductor wafer 1770′ is fabricated by IC fab 1730 using mask(s) 1760′ to form IC device 1740. In some embodiments, the IC fabrication includes performing one or more lithographic exposures based at least indirectly on IC design layout diagram 1710′. Semiconductor wafer 1770′ includes a silicon substrate or other proper substrate having material layers formed thereon. Semiconductor wafer 1770′ further includes one or more of various doped regions, dielectric features, multilevel interconnects, and the like (formed at subsequent manufacturing steps).

In an embodiment, a semiconductor device comprises plurality of cells, a plurality of active regions, a plurality of gate regions, a plurality of sources and drains, and a plurality of power rails. The cells are arranged in an array of rows and columns and include one or more taller cells, one or more shorter cells, and one or more one-half-height (OHH) cells. The shorter cell has a smaller cell height than the taller cell. The OHH cell has a cell height larger than the cell height of the taller cell. The active regions are formed in each cell. The active regions include a first conductivity type and a second conductivity type opposite to the first conductivity type. The gate region extends across the active regions. The sources and drains are formed in the active regions on opposite sides of the gate region. The power rails include first and second power rails respectively defining top and bottom boundaries of a cell.

In another embodiment, a semiconductor device comprises a plurality of cells, a plurality of active regions, a plurality of gate regions, a plurality of sources and drains, and a plurality of power rails. The cells are arranged in an array of rows and columns and include one or more average height cells, a plurality of unit cells, and one or more one-half-height (OHH) cells. The taller cell has a larger cell height than the average height cell. The shorter cell has a smaller cell height than the average height cell. The OHH cell has a larger cell height than the taller cell. The active regions are formed in each cell. The active region include a first conductivity type and a second conductivity type opposite to the first conductivity type. The gate region extends across the active regions. The sources and drains are formed in the active regions on opposite sides of the gate region. The power rails include first and second power rails respectively defining top and bottom boundaries of a cell

In another embodiment, a method of manufacturing a semiconductor device comprises fabricating, on a semiconductor substrate, a plurality of cells arranged in an array of rows and columns, including: forming active regions in each cell; forming a gate region across the active regions; and forming source and drain regions in the active regions on opposite sides of the gate region. The cells include one or more taller cells, one or more shorter cells, and one or more one-half-height (OHH) cells. The shorter cell has a smaller cell height than the taller cell. The OHH cell has a cell height substantially equal to the sum of the cell height of one of the taller and shorter cells and half the cell height of the other of the taller or shorter cells. The active regions include a first conductivity type and a second conductivity type opposite to the first conductivity type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a plurality of cells arranged in an array of rows and columns, wherein the plurality of cells include:
one or more taller cells;
one or more shorter cells having a smaller cell height than the taller cell; and
one or more one-half-height (OHH) cells having a cell height larger than the cell height of the taller cell;
a plurality of active regions formed in each cell, wherein the active regions include a first conductivity type and a second conductivity type opposite to the first conductivity type;
a plurality of gate regions, each extending across the active regions;
a plurality of sources and drains formed in the active regions on opposite sides of the gate region; and
a plurality of power rails including first and second power rails respectively defining top and bottom boundaries of a cell.

2. The semiconductor device of claim 1, wherein:
the taller cell is in a first row;
the shorter cell is in a second row; and
the OHH cell spans the first and second rows, wherein the OHH cell has a top edge that aligns with a top edge of the taller cell and a bottom edge that aligns with a center of the shorter cell.

3. The semiconductor device of claim 1, wherein:
a tall cell is in a first row;
a short cell is in a second row; and
an OHH cell is in the first and second rows, wherein the OHH cell has a bottom edge that aligns with a bottom edge of the tall cell and a top edge that aligns with a center of the tall cell.

4. The semiconductor device of claim 1, wherein the OHH cell has a cell height substantially equal to the cell height of the taller cell and half the cell height of the shorter cell.

5. The semiconductor device of claim 1, wherein the OHH cell has a cell height substantially equal to the cell height of the shorter cell and half the cell height of the taller cell.

6. The semiconductor device of claim 1, further comprising one or more average height cells having an average cell height larger than the cell height of the shorter cell and smaller than the cell height of the taller cell.

7. The semiconductor device of claim 1, wherein:
a first average height cell is in a first row;
a second average height cell the short cell is in a second row; and
an OHH cell spans the first and second rows, wherein the OHH cell has a top edge that aligns with a top edge of the first average height cell and a bottom edge that aligns with a center of the second average height cell.

8. A semiconductor device comprising:
a plurality of cells arranged in an array of rows and columns, wherein the plurality of cells includes:
one or more average height cells;
a plurality of unit cells including:
a taller cell having a larger cell height than the average height cell; and
a shorter cell having a smaller cell height than the average height cell; and
one or more one-half-height (OHH) cells having a larger cell height than the taller cell;
a plurality of active regions formed in each cell, wherein the active region include a first conductivity type and a second conductivity type opposite to the first conductivity type;
a plurality of gate regions, each extending across the active regions;
a plurality of sources and drains formed in the active regions on opposite sides of the gate regions; and
a plurality of power rails including first and second power rails respectively defining top and bottom boundaries of a cell.

9. The semiconductor device of claim 8, wherein:
the taller cell is in a first row;
the shorter cell is in a second row; and
the OHH cell spans the first and second rows, wherein the OHH cell has a top edge that aligns with a top edge of the taller cell and a bottom edge that aligns with a center of the shorter cell.

10. The semiconductor device of claim 9, wherein:
the shorter cell is in a first row;
the taller cell is in a second row; and
the OHH cell spans the first and second rows, wherein the OHH cell has a top edge that aligns with a top edge of the shorter cell and a bottom edge that aligns with a center of the taller.

11. The semiconductor device of claim 8, wherein:
a first average height cell is in a first row;
a second average height cell is in a second row; and
the OHH cell spans the first and second rows, wherein the OHH cell has a top edge that aligns with a top edge of the first average height cell and a bottom edge that aligns with a center of the second average height cell.

12. The semiconductor device of claim 8, further comprising:
a first taller cell in a first row;
a second taller cell is in a second row; and
an OHH cell that spans the first and second rows and that has a cell height substantially equal to the sum of a cell height of the first taller cell and half a cell height of the second taller cell.

13. The semiconductor device of claim 8, further comprising:
a first shorter cell in a first row;
a second shorter cell is in a second row; and
an OHH cell that spans the first and second rows and that has a cell height substantially equal to the sum of a cell height of the first shorter cell and half a cell height of the second shorter cell.

14. The semiconductor device of claim 11, further comprising a merged cell that spans the first and second rows.

15. The semiconductor device of claim 8, further comprising a plurality of taller cells and a plurality of shorter cells arranged to alternate across rows.

16. The semiconductor device of claim 8, further comprising adjacent pairs of taller and shorter cells arranged to alternate across rows.

17. A method of manufacturing a semiconductor device, comprising:
fabricating, on a semiconductor substrate, a plurality of cells arranged in an array of rows and columns, wherein fabricating the plurality of cells includes:
fabricating a pair of first power rails that define a taller cell;
fabricating a pair of second power rails that define a shorter cell, wherein the shorter cell has a smaller cell height than the taller cell;
fabricating a pair of third power rails that define a one-half-height (OHH) cell, wherein the OHH cell has a cell height substantially equal to the sum of the cell height of one of the taller and shorter cells and half the cell height of the other of the taller and shorter cells;
patterning one or more active regions in each cell;
forming a gate structure across the active regions; and
doping the active regions to form source and drain regions on opposite sides of the gate structure.

18. The method of claim 17, further comprising:
placing the taller and shorter cells in a first column across first and second rows of the layout; and
placing the OHH cell in a second column such that the OHH cell spans the first and second rows.

19. The method of claim 17, further comprising:
forming a unit cell by:
respectively placing a pair of cut regions over top and bottom edges of the taller or shorter cell; and
respectively placing a pair of power rails over the cut regions.

20. The method of claim 17, further comprising:
forming an OHH cell by:
respectively placing a pair of cut regions over top and bottom edges of the OHH cell;
placing a first power rail over the cut region at the top edge of the OHH cell; and
placing a second power rail between the cut regions; and
placing a third power rail such that the cut region at the bottom edge of the OHH cell is disposed between the second and third power rails.
